(19) United States
(12) Patent Application Publication
(10) Pub. No.: US 2023/0207684 A1
(43) Pub. Date: Jun. 29, 2023

(54) SPLIT-GATE MOSFET AND MANUFACTURING METHOD THEREOF

(71) Applicant: Hangzhou Silicon-Magic Semiconductor Technology Co., Ltd., Hangzhou City (CN)

(72) Inventors: Jinyong Cai, Hangzhou City (CN); Shida Dong, Hangzhou City (CN); Jiakun Wang, Hangzhou City (CN)

(21) Appl. No.: 17/986,977

(22) Filed: Nov. 15, 2022

(30) Foreign Application Priority Data
Dec. 29, 2021 (CN) 202111635879.3

(51) Int. Cl. H01L 29/78; H01L 29/423; H01L 29/40; H01L 29/66

(52) U.S. Cl. CPC H01L 29/7813; H01L 29/4236; H01L 29/407; H01L 29/66734

(57) ABSTRACT

Disclosed is a split-gate MOSFET and a manufacturing method, comprising: forming a cavity in a semiconductor layer; form a first trench based on the cavity; forming a second trench communicated with the first trench and extending in a same direction with the second trench; forming a first dielectric layer and a second dielectric layer; forming a first conductor located in the second trench and isolated from the semiconductor layer by the first dielectric layer; forming a third dielectric layer covering a surface of the first conductor; forming a second conductor located in the first trench, isolated from the semiconductor layer by the second dielectric layer, and isolated from the second conductor by the third dielectric layer; forming a body region adjacent to the first trench, wherein an inner diameter of the first trench is larger than an inner diameter of the second trench. The manufacturing method expands a process window.

### CROSS-REFERENCE TO RELATED APPLICATIONS

The present application claims the priority to Chinese Patent Application No. 202111635879.3, filed on Dec. 29, 2021, entitled by “SPLIT-GATE MOSFET AND MANUFACTURING METHOD THEREOF”, and published as CN114678276A on Jun. 28, 2022, which is incorporated herein by reference in its entirety.

### FIELD OF TECHNOLOGY

The present disclosure relates to a field of semiconductor technology, in particular to a split-gate MOSFET and a manufacturing method of a split-gate MOSFET.

### BACKGROUND

A trench power MOSFET (Metal Oxide Semiconductor Field Effect Transistor) is a kind of high efficiency switching device developed after planar VDMOS (Vertical Double-diffused Metal Oxide Semiconductor Field Effect Transistor. The trench power MOSFET is widely used in power electronics field because of its high input impedance, low driving current, fast switching speed and good high-temperature characteristics. High breakdown voltage, large current and low on-resistance are most critical indexes of a power MOSFET, wherein the breakdown voltage is related to the on-resistance. In a design process of a MOSFET, it is difficult to implement high breakdown voltage and low on-resistance at the same time, so that it is necessary to tradeoff between them.

In order to make the breakdown voltage as high as possible and the on-resistance as low as possible, a new type of split-gate MOSFET comes into being, and compared with an ordinary trench MOSFET structure, a main feature of a split-gate MOSFET is that, a deep trench split gate is added and is short-connected with a source, and a split gate is used to balance electric field for improving a withstand voltage of the device.

However, in the existing split-gate MOSFET, because the trench has a small critical dimension (CD), a dielectric layer between a first conductor and a second conductor in the trench is prone to generate voids after deposition, which may affect mechanical strength and electrical performance of the device, and there is also a risk of leakage.

Therefore, it is desirable to provide an improved method of manufacturing a split-gate MOSFET, to avoid generating a void in the dielectric layer between the first conductor and the second conductor in the trench and reduce the risk of leakage.

### SUMMARY

In view of the above problems, an objective of the present disclosure is to provide a split-gate MOSFET and a manufacturing method thereof, so as to avoid creating a void in a dielectric layer between a first conductor and a second conductor in a trench, and reduce a risk of leakage.

According to an aspect of the present disclosure, a manufacturing method of a split-gate MOSFET is provided, and comprises: forming a cavity extending from an upper surface of a semiconductor layer of a first dopant type to an interior of the semiconductor layer; removing a portion, which is located on a sidewall of the cavity, of the semiconductor layer, to form a first trench; forming a second trench communicated with the first trench, wherein the first trench and the second trench extend in a same direction; forming a first dielectric layer covering an inner surface of the second trench, and a second dielectric layer covering on an inner surface of the first trench; forming a first conductor which is located in the second trench, and is isolated from the semiconductor layer by the first dielectric layer; forming a third dielectric layer covering a surface of the first conductor; forming a second conductor located in the first trench, wherein the second conductor is isolated from the semiconductor layer by the second dielectric layer, and is isolated from the first conductor by the third dielectric layer; and forming a body region of a second dopant type which is located in the semiconductor layer and adjacent to the first trench, wherein an inner diameter of the first trench is larger than an inner diameter of the second trench.

Optionally, an oxidation process is performed to convert the portion, which is located on the sidewall of the cavity, of the semiconductor layer into an oxide layer, and the oxide layer is then removed to form the first trench, wherein an inner diameter of a bottom of the first trench is smaller than an inner diameter of a top of the first trench, and an inner diameter of the second trench substantially keeps consistent with the inner diameter of the bottom of the first trench.

Optionally, an inner diameter of the oxide layer gradually increases from bottom to top, so that the inner diameter of the first trench gradually increases from bottom to top.

Optionally, a thickness of the portion, which is located on the sidewall of the cavity and to be removed, of the semiconductor layer is controlled by adjusting an oxidant concentration in the oxidation process.

Optionally, a thickness of the first dielectric layer is greater than a thickness of the second dielectric layer.

Optionally, the manufacturing method also comprises: forming a source region of the first dopant type in the body region; forming an interlayer dielectric layer on the source region; and forming a source electrode on the interlayer dielectric layer.

Optionally, the manufacturing method also comprises: forming a body contact region of the second dopant type in the body region; and forming a conductive channel penetrating the interlayer dielectric layer and the source region to reach the body contact region, wherein the source electrode is connected to the body contact region via the conductive channel.

Optionally, the semiconductor layer is formed on a semiconductor substrate, the semiconductor substrate is located on a lower surface of the semiconductor layer, the upper surface of the semiconductor layer is opposite to the lower surface of the semiconductor layer, and the manufacturing method further comprises: forming a drain electrode located on the lower surface of the semiconductor substrate.

According to a second aspect of the present disclosure, a split-gate MOSFET is provided, and comprises: a semiconductor layer of a first dopant type; a first trench extending from an upper surface of the semiconductor layer to an interior of the semiconductor layer, and a second trench communicated with a bottom of the first trench, wherein the first trench and the second trench extend in a same direction; a first dielectric layer covering an inner surface of the second trench, a second dielectric layer covering an inner surface of the first trench, and a third dielectric layer between the first dielectric layer and the second dielectric layer; a first conductor located in the second trench and a second conductor located in the first trench, wherein the first conductor is isolated from the semiconductor layer by the first dielectric layer, the second conductor is isolated from the semiconductor layer by the second dielectric layer, and the first conductor is isolated from the second conductor by the third dielectric layer; and a body region of a second dopant type which is located in the semiconductor layer and adjacent to the first trench, wherein the first trench is formed by removing a portion, which is located on a sidewall of a cavity, of the semiconductor layer, an inner diameter of the first trench is larger than an inner diameter of the second trench.

Optionally, the inner diameter of the first trench gradually increases from bottom to top.

Optionally, an inner diameter of a bottom of the first trench is smaller than an inner diameter of a top of the first trench, and an inner diameter of the second trench substantially keeps consistent with the inner diameter of the bottom of the first trench.

Optionally, a thickness of the first dielectric layer is greater than a thickness of the second dielectric layer.

Optionally, the split-gate MOSFET also comprises: a source region of the first dopant type in the body region; an interlayer dielectric layer on the source region; and a source electrode on the interlayer dielectric layer.

Optionally, the split-gate MOSFET also comprises a body contact region of the second dopant type in the body region; and a conductive channel penetrating the interlayer dielectric layer and the source region to reach the body contact region, wherein the source electrode is connected to the body contact region via the conductive channel.

Optionally, the split-gate MOSFET also comprises: a semiconductor substrate located on a lower surface of the semiconductor layer, wherein the upper surface of the semiconductor layer is opposite to the lower surface of the semiconductor layer; and a drain electrode located on the lower surface of the semiconductor substrate.

In the split-gate MOSFET and the manufacturing method of the split-gate MOSFET according to embodiments of the present disclosure, the first trench with a large aperture is formed by utilizing the cavity formed by etching, so that the inner diameter of the first trench is larger than the inner diameter of the second trench, thereby being beneficial to expanding process window, preventing a void from being created in the third dielectric layer, and at the same time, the device size is not affected.

### BRIEF DESCRIPTION OF THE DRAWINGS

The above and other objects, features and advantages of the present disclosure will become more apparent from the following description of the present disclosure embodiment with reference to the accompanying drawings, in which:

FIG. 1 shows a cross-sectional view of a conventional split-gate MOSFET;

FIG. 2 shows a cross-sectional view of a split-gate MOSFET according to an embodiment of the present disclosure;

FIGS. 3a-3i show cross-sectional views at various stages of a manufacturing method of a split-gate MOSFET according to an embodiment of the present disclosure.

### DETAILED DESCRIPTION OF THE EMBODIMENTS

The present disclosure will be described in more detail below with reference to the accompanying drawings. Throughout the various figures, like elements are denoted by the same or similar reference numerals. For the sake of clarity, various parts in the drawings are not drawn to scale. In addition, some well-known parts may not be shown. For the sake of simplicity, the semiconductor structure after several steps may be described in one diagram.

In a case that one layer or one region is referred to as being located “on” or “above” another layer or another region when a structure of a device is described, it means the one layer or the one region is located above another layer or another region, with or without additional layers or additional regions therebetween. Moreover, in a case that the device is turned upside down, the one layer or the one region will be “under” or “below” another layer or another region.

In a case that the one layer or the one region is located directly on another layer or another region, the expression will be “A is located directly on B”, “A is located on and adjacently contacted with B”.

In the present disclosure, the term “semiconductor structure” refers to a generic designation of an entire semiconductor structure formed in the various steps of manufacturing a device, including all layers and/or regions that have been formed.

Many specific details of the present disclosure, such as a structure, a material, a dimension, a processing process and a technique of the device, are described below, so that the present disclosure can be clearly understood. However, as will be understood by those skilled in the art, the present disclosure may be achieved without these specific details.

Unless specifically noted below, portions of the semiconductor device may be constructed of materials well known to those skilled in the art. Semiconductor materials include, for example, Group III-V semiconductors, such as GaAs, InP, GaN, SiC, and Group IV semiconductors, such as Si, Ge. A gate conductor may be formed of various materials capable of conducting electricity, such as a metal layer, a doped polysilicon layer, or a stacked gate conductor comprising a metal layer and a doped polysilicon layer, or other conductive materials, such as TaC, TiN, TaSiN, HfSiN, TiSiN, TiCN, TaAlC, TiAlN, TaN, PtSix, Ni3Si, Pt, Ru, W, and combinations of the various conductive materials. A gate dielectric layer may be formed of SiO₂ or a material which has a dielectric constant greater than SiO₂, and includes, for example, an oxide, a nitride, a silicate, an aluminate, and/or a titanate. Moreover, the gate dielectric may be formed not only from a material well known to those skilled in the art, but also from a material to be developed for the gate dielectric layer in the future.

The present disclosure can be presented in various forms, and some examples will be described below.

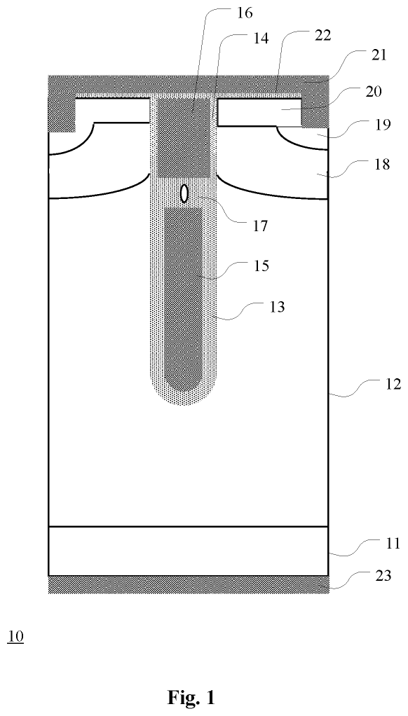

FIG. 1 shows a cross-sectional view of a conventional split-gate MOSFET.

As shown in FIG. 1, the split-gate MOSFET 10 includes a semiconductor substrate 11 of a first conductivity type, an epitaxial layer 12 of the first conductivity type is provided on an upper surface of the semiconductor substrate 11 of the first conductivity type, a trench is located in the epitaxial layer 12 of the first conductivity type, a sidewall of the trench is covered with a first dielectric layer 13 and a second dielectric layer 14. A core portion of the trench is a first conductor 15 located in a lower half of the trench, and a second conductor 16 located in an upper half of the trench. A third dielectric layer 17 is provided between the first conductor 15 and the second conductor 16, the first conductor 15 is isolated from the epitaxial layer 12 of the first conductivity type by the first dielectric layer 13. A body region 18 of the second conductivity type is located on the epitaxial layer 12, and a heavily doped region 19 of the second conductivity type is located in an upper portion of the body region 18. The second conductor 16 is isolated from the body region 18 of the second conductivity type by the second dielectric layer 14. A heavily doped source region 20 of the first conductivity type is located on the body region 18 of the second conductivity type, a metal layer 21 is led out through a hole, which is formed in the heavily doped source region 20 of the first conductivity type and the heavily doped region 19 of the second conductivity type. The metal layer 21 and the second conductor 16 each are separated from the heavily doped source region 20 of the first conductivity type by a fourth dielectric layer 22, and a metal layer 23 is formed on a back surface of the semiconductor substrate 11.

In the split-gate MOSFET 10 shown in FIG. 1, since a critical dimension of the trench is small, when the third dielectric layer 17 is formed between the first conductor 15 and the second conductor 16, a void may be easily created in the third dielectric layer 17, which may affect mechanical strength and electrical performance of the device.

Noting the above problems affecting device yield, the inventors of the present disclosure improve the conventional split-gate MOSFET, so as to avoid creating a void in the dielectric layer between the first conductor and the second conductor.

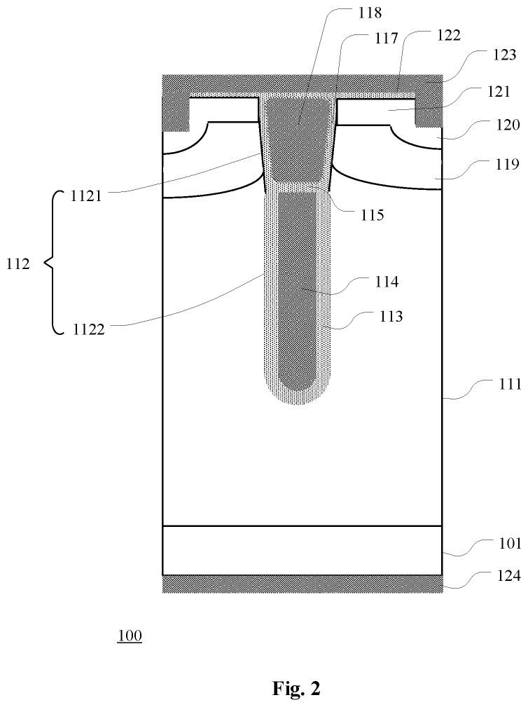

FIG. 2 shows a cross-sectional view of a split-gate MOSFET according to an embodiment of the present disclosure.

In the present disclosure, a semiconductor layer has a first dopant type, the first dopant type is one of an N dopant type (N-type) and a P dopant type (P-type), and the second dopant type is the other one of the N dopant type and the P dopant type. In order to form an epitaxial semiconductor layer or a region of N dopant type, N-type dopants (e.g., P, As) may be implanted into the epitaxial semiconductor layer or the region. In order to form an epitaxial semiconductor layer or a region of P dopant type, P-type dopants (e.g., B) may be doped into the epitaxial semiconductor layer or the region. In an example, the semiconductor layer is of N dopant type.

Specifically, the split-gate MOSFET 100 comprises a semiconductor substrate 101 and a semiconductor layer 111 disposed on the semiconductor substrate 101. In this embodiment, the semiconductor layer 111 is an epitaxial semiconductor layer, and the semiconductor substrate 101 has a first dopant type, for example, an N dopant type. The epitaxial semiconductor layer 111 is located on a surface, which is opposite to a drain electrode 124, of the semiconductor substrate 101, that is the epitaxial semiconductor layer 111 is located on a first surface of the semiconductor substrate 101. The epitaxial semiconductor layer 111 is, for example, composed of silicon. The epitaxial semiconductor layer 111 is a lightly doped layer with respect to the semiconductor substrate 101. A second surface of the semiconductor substrate 101 is thinned by a thinning technique, and the drain electrode 124 is formed on the second surface. In some embodiments, a buffer layer is also provided between the semiconductor substrate 101 and the epitaxial semiconductor layer 111, the dopant type of the buffer layer is the same as the semiconductor substrate, in order to reduce interface instability between the semiconductor substrate and the epitaxial semiconductor layer due to a defect of the semiconductor substrate.

The split-gate MOSFET further comprises: a trench 112 extending from an upper surface of the epitaxial semiconductor layer 111 into an interior of the epitaxial semiconductor layer 111; a dielectric layer and an electrode conductor located inside the trench; and a body region 119 of the second dopant type, which is located in the semiconductor layer and adjacent to the trench 112, wherein the trench terminates in the epitaxial semiconductor layer 111.

Specifically, the trench 112 comprises a first trench 1121 extending from an upper surface of the semiconductor layer 111 to an interior of the semiconductor layer 111, and a second trench 1122 communicated with a bottom of the first trench 1121. The first trench 1121 and the second trench 1122 extend in a same direction, and the first trench 1121 is formed by removing a portion, which is located on the sidewall of a cavity, of the semiconductor layer 111, so that a process window may be large, which is beneficial to perform material filling in the trench. An inner diameter of the bottom of the first trench 1121 is smaller than an inner diameter of a top of the first trench 1121, and an inner diameter of the second trench 1122 substantially keeps consistent with the inner diameter of the bottom of the first trench 1121, so that an inner diameter of the first trench 1121 is regarded to be larger than the inner diameter of the second trench 1122. Optionally, the inner diameter of the first trench 1121 gradually increases from bottom to top.

A dielectric layer in the trench comprises a first dielectric layer 113 covering an inner surface of the second trench 1122, a second dielectric layer 117 covering an inner surface of the first trench 1121, and a third dielectric layer 115 positioned between the first dielectric layer 113 and the second dielectric layer 117. Optionally, the first dielectric layer 113 has a thickness greater than that of the second dielectric layer 117. Electrode conductors in the trench comprise a first conductor 114 located in the second trench 1122 and a second conductor 118 located in the first trench 1121, wherein the first conductor 114 is isolated from the epitaxial semiconductor layer 111 by the first dielectric layer 113, and the second conductor 118 is isolated from the epitaxial semiconductor layer 111 by the second dielectric layer 117. In this embodiment, the first conductor 114 is a shielding conductor, the second conductor 118 is a gate conductor, the second dielectric layer 117 is a gate dielectric layer, and the shielding conductor 114 is isolated from the gate conductor 118 by the third dielectric layer 115. A junction depth of the body region 119 is not deeper than an extension depth of the gate conductor 118 in the trench.

The split-gate MOSFET further comprises: a source region 121 of the first dopant type in the body region 119; a body contact region 120 of the second dopant type in the body region 119; an interlayer dielectric layer 122 formed on the source region 121 and the gate conductor 118; a conductive channel that penetrates the interlayer dielectric layer 122 and the source region 121 to reach the body contact region 120, and is located immediately adjacent to the source region 121; and a source electrode 123 which is formed on the interlayer dielectric layer 122 and is connected to the body contact region 120 via the conductive channel. The interlayer dielectric layer 122 may be an oxide layer having a certain thickness, for example, a silicon oxide layer.

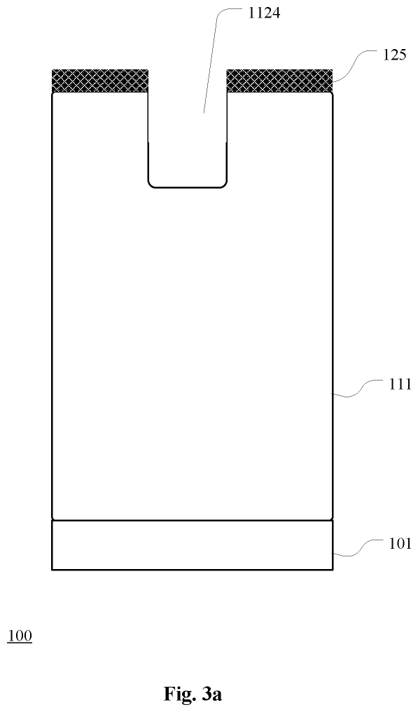

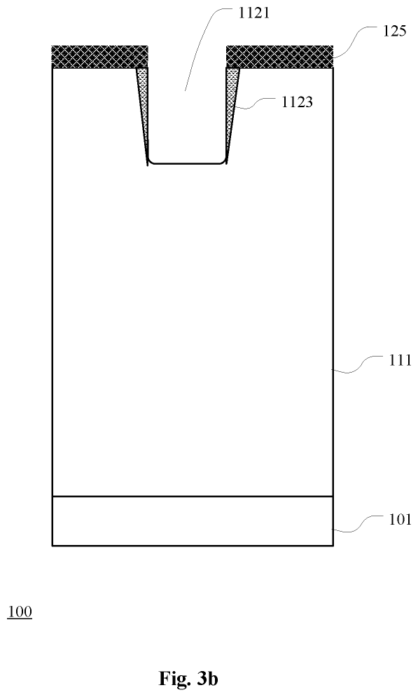

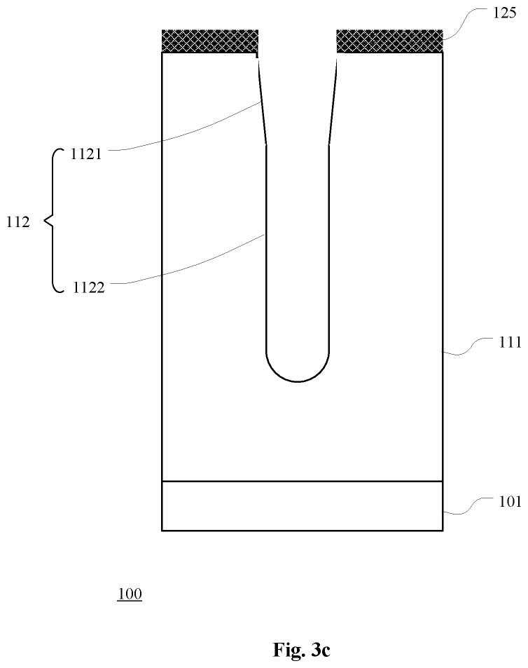

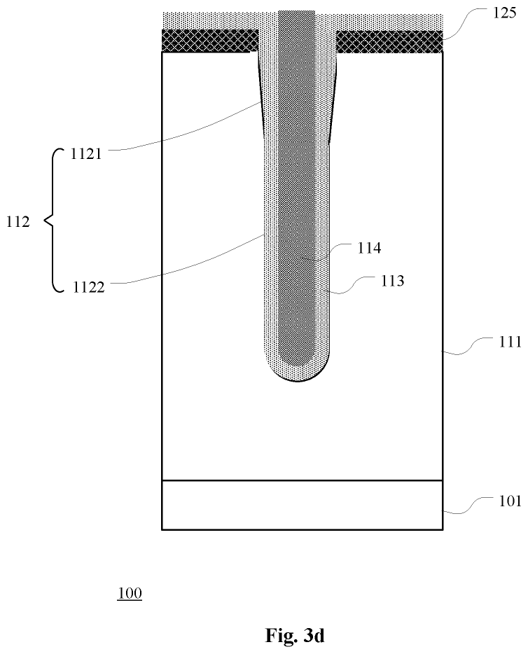

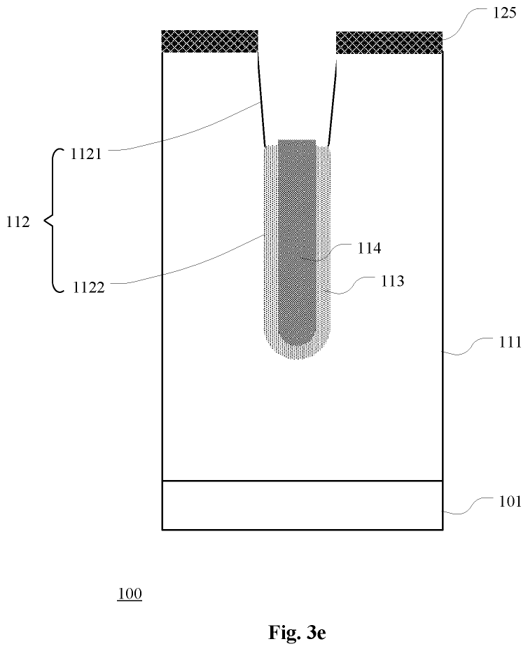

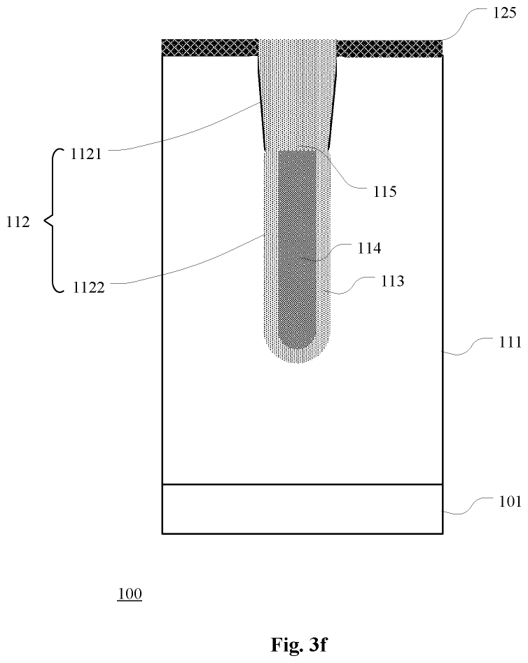

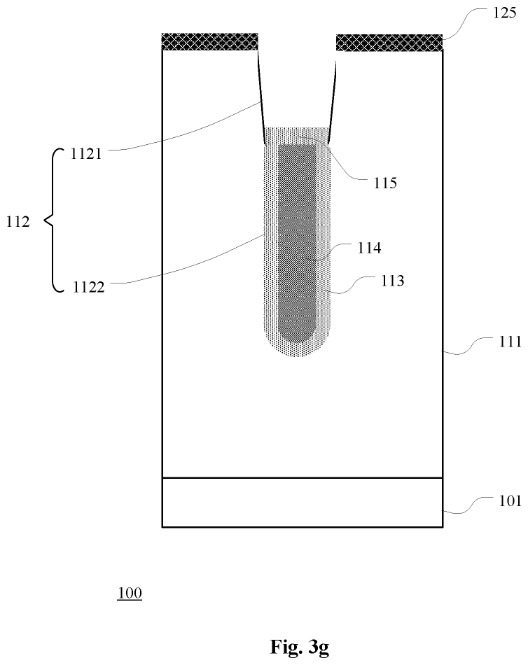

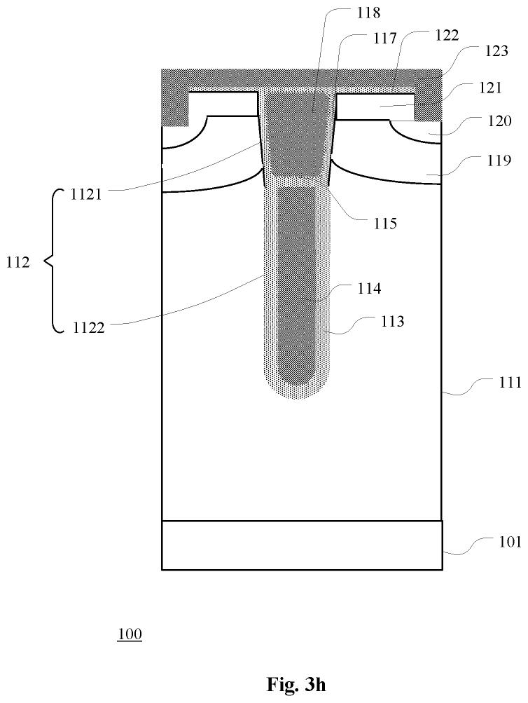

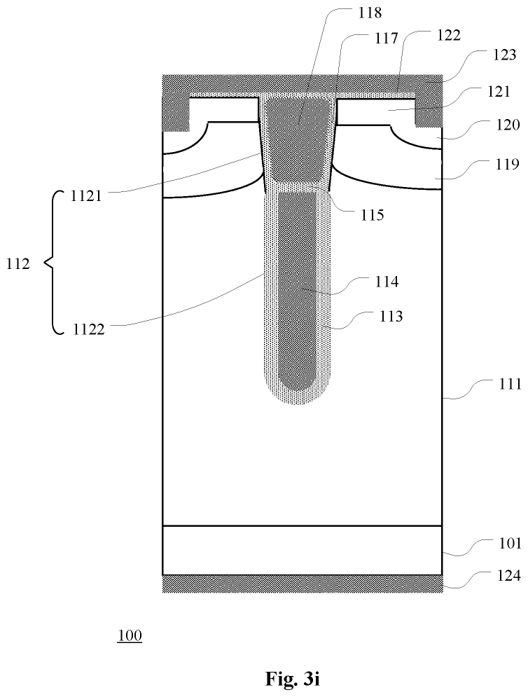

FIGS. 3a-3i show cross-sectional views at various stages of a manufacturing method of a split-gate MOSFET according to an embodiment of the present disclosure.

Step S1: a first trench 1121 extends from an upper surface to an interior of a semiconductor layer 111, which is of the first dopant type, and is formed, as shown in FIGS. 3a-3b.

In step S1, in the present disclosure, the split-gate MOSFET comprises: a semiconductor substrate 101 and a semiconductor layer 111 on the semiconductor substrate 101, wherein the semiconductor layer 111 is an epitaxial semiconductor layer; and an oxide layer formed on the epitaxial semiconductor layer 111. Then, a photoresist layer is formed on the oxide layer, and then an etching process is performed. By employ dry etching, such as ion milling etching, plasma etching, reactive ion etching, laser ablation, or by selective wet etching using an etching solution, the etching process is used to etch down from an opening in the photoresist mask to form a corresponding opening in the oxide layer, so that the oxide layer can be patterned and serve as a first hard mask 125. Due to etching selectivity, the etching process can be stopped on the surface of the epitaxial semiconductor layer 111. After the first hard mask 125 is formed, the photoresist layer is removed by ashing or dissolving in a solvent.

By use of the first hard mask 125, the epitaxial semiconductor layer 111 is further etched by the above-described known etching process to further form a cavity 1124 extending from the upper surface to the interior of the semiconductor layer 111 of the first dopant type. The cavity 1124 extends into the epitaxial semiconductor layer 111 from the upper surface of the epitaxial semiconductor layer 111. For example, by controlling etching time, a depth of the cavity 1124 can be controlled. The cavity 1124 terminates in the epitaxial semiconductor layer 111.

Further, as shown in FIG. 3b, a portion, which is located on a sidewall of the cavity 1124, of the semiconductor layer 111 is removed, so that a first trench 1121 is formed. For example, by performing an oxidation process, the portion, which is located on the sidewall of the cavity 1124, of the semiconductor layer 111 can be oxidized to form an oxide layer 1123, and then the oxide layer 1123 is removed. A thickness of the portion, which is located on the sidewall of the cavity and is to be removed by etching, of the semiconductor layer is controlled by adjusting oxidant and/or etchant concentration, so that an inner diameter of a bottom of the first trench 1121 is smaller than an inner diameter of a top of the first trench 1121. For example, when the oxidant concentration is controlled to gradually decrease from top to bottom, an inner diameter of the oxide layer 1123 gradually increases from bottom to top, so that the inner diameter of the first trench 1121 gradually increases from bottom to top.

Step S2: a second trench 1122 communicated with the first trench 1121 is formed by use of the first trench 1121, and the first trench 1121 and the second trench 1122 extend in a same direction as shown in FIG. 3c. In step S2, an inner diameter of the second trench 1122 substantially keeps consistent with the inner diameter of the bottom of the first trench 1121. The first trench 1121 is in communication with the second trench 1122, thus the first trench 1121 and the second trench 1122 can be taken as a whole and referred to as the trench 112 in a subsequent process.

In some embodiments, the steps referring to FIGS. 3b and 3c may be exchanged, that is, the cavity 1124 and the second trench 1122 can be formed before the portion, which is located on the sidewall of the cavity 1124, of the semiconductor layer is etched to form the first trench 1121.

Step S3: dielectric layers and electrode conductors are formed in the trench 112 as shown in FIGS. 3d-3h.

In step S3, a first dielectric layer 113 covering an inner surface of the second trench 1122, a second dielectric layer 117 covering an inner surface of the first trench 1121, a first conductor 114 positioned in the second trench 1122, a third dielectric layer 115 covering a surface of the first conductor 114, and a second conductor 118 positioned in the first trench 1121 are formed.

Specifically, the first dielectric layer 113 and the first conductor 114 are formed in the second trench 1122, the first dielectric layer 113 is located on sidewall and bottom of the second trench 1122 and isolates the first conductor 114 from the semiconductor layer 111; the third dielectric layer 115 is formed on top of the first conductor 114; the second dielectric layer 117 and the second conductor 118 are formed in the first trench 1121, the second dielectric layer 117 is positioned on a sidewall of the first trench 1121 and isolates the second conductor 118 from the semiconductor layer 111; wherein, the dielectric layers comprise the first dielectric layer 113, the second dielectric layer 117, and the third dielectric layer 115; the electrode conductors comprise the first conductor 114 and the second conductor 118. In this embodiment, the first conductor 114 is a shielding conductor, the second conductor 118 is a gate conductor and the second dielectric layer 117 is a gate dielectric layer.

As an example, the first dielectric layer 113 is formed inside the trench and on an upper surface of the epitaxial semiconductor layer 111 by thermal oxidation or chemical vapor deposition, that is, the first dielectric layer 113 covers bottom and sidewall of the trench, and the upper surface of the epitaxial semiconductor layer 111; the first dielectric layer 113 may be composed of an oxide or a nitride, for example, silicon oxide or silicon nitride.

Subsequently, the shielding conductor is formed inside the trench and on the upper surface of the epitaxial semiconductor layer 111 by low-pressure chemical vapor deposition. The shielding conductor is isolated from the epitaxial semiconductor layer 111 by the first dielectric layer 113.

The shielding conductor is first subjected to chemical mechanical grinding, and then the shielding conductor is selectively etched back with respect to the first dielectric layer 113, so that a portion, which is positioned on the upper surface of the epitaxial semiconductor layer 111 and inside the first trench 1121, of the shielding conductor is removed, and a remaining portion of the shielding conductor is regarded as the shielding conductor 114 shown in FIG. 2. The back etching process may be a dry etching process, and the shielding conductor 114 may be composed of polysilicon.

Subsequently, by use of the above-mentioned known etching process, the first dielectric layer 113 is selectively etched with respect to the epitaxial semiconductor layer 111, and a portion, which is positioned on the upper surface of the epitaxial semiconductor layer 111 and inside the first trench 1121, of the first dielectric layer 113 is removed, such that the remaining portion of the first dielectric layer 113 is positioned between the sidewall of the trench and the shielding conductor 114, and the first dielectric layer 113 does not cover a top of the shielding conductor 114, for example, a surface of the first dielectric layer 113 is lower than a surface of the shielding conductor 114. The etching process can be a wet etching process, which is mainly performed on a relatively flat film surface to form a roughness surface, thus increasing optical path and reducing light reflection. Diluted HF or BOE (Buffered-Oxide-Etch) solution can be used for the wet etching process. In another embodiment, this step of the etching process may also be omitted, so that the first dielectric layer 113 is conformal with the subsequently formed third dielectric layer 115, and then the first dielectric layer 113 and the third dielectric layer 115 can be etched together. Whether the specific etching process of this step is omitted or not can be decided by those skilled in the art according to an actual process requirement.

Subsequently, the third dielectric layer 115 is conformally formed on tops of the shielding conductor 114 and the first dielectric layer 113 by a plasma enhanced chemical vapor deposition process. The third dielectric layer 115 covers the tops of the shielding conductor and the first dielectric layer 113, and is located on the sidewall of the first trench 1121 and the upper surface of the epitaxial semiconductor layer 111. The third dielectric layer 115 may be composed of an oxide or a nitride, for example, silicon oxide or silicon nitride.

In this example, since the inner diameter of the first trench 1121 which has been previously provided is larger than the inner diameter of the second trench 1122, thereby facilitating enlargement of the process window, so as to avoid creating a void in the third dielectric layer 115 during a process for forming the third dielectric layer 115 without affecting the device size.

Subsequently, a portion, which is positioned on the upper surface of the epitaxial layer, of the third dielectric layer 115 is removed by a CMP (chemical mechanical grinding) process, and then the third dielectric layer 115 in the trench is etched back by use of BOE (Buffered-Oxide-Etch) solution, so that a portion, which is positioned on the top of the shielding conductor 114, of the third dielectric layer 115 is remained with a certain thickness. In the present disclosure, the method of forming the third dielectric layer 115 is not limited and a person skilled in the art can select an appropriate method to form the third dielectric layer 115 according to an actual situation.

Subsequently, an oxide layer, which serves as the gate dielectric layer 117 is formed on the sidewall of the first trench 1121 by performing a thermal oxidation process, so that the sidewall of the trench is covered by the gate dielectric layer 117. Usually, the thermal oxidation process is implemented by performing a chemical reaction between silicon and a gas containing an oxidizing substance, such as water vapor and oxygen, at high temperature, so as to form a dense silicon dioxide (SiO₂) film on a surface of silicon wafer, which is an important process in silicon planar technology.

Further, by a low-pressure chemical vapor deposition process, polysilicon is filled in the trench covered with the gate dielectric layer 117 to form a gate conductor 118, which comprises a first portion located in the trench and a second portion located on the upper surface of the trench. A portion, which is positioned on the upper surface of the epitaxial semiconductor layer 111, of the first portion of the gate conductor is then removed by back etching or chemical mechanical planarization, such that an upper end of the gate conductor 118 terminates at an opening of the trench. Alternatively, a portion of the conductor layer forming the gate conductor 118 is selectively removed with respect to the epitaxial semiconductor layer 111, and the conductor layer is etched back, so that the gate conductor 118 in the trench is located at an upper surface of the epitaxial semiconductor layer 111. The shielding conductor 114 and the gate conductor 118 are insulated from each other by the third dielectric layer 115, which has a significant mass and thickness to support a potential difference that may exist between the shielding conductor 114 and the gate conductor 118.

After the dielectric layer and the electrode conductor in the trench 112 is formed, the first hard mask 125 may be removed with respect to the epitaxial semiconductor layer 111 by use of a selective etchant.

Step S4: a body region in the semiconductor layer 111 is formed adjacent to the first trench 1121, the body region has the second dopant type, wherein the second dopant type is opposite to the first dopant type.

In step S4, by use of conventional bulk implantation and drive-in techniques, a first ion implantation process is performed to form the body region 119 of the second dopant type adjacent to the first trench 1121 in the epitaxial semiconductor layer 111, as shown in FIGS. 3h-3i.

Further, a second ion implantation process is performed to form a source region 121 of the first dopant type in the body region 119. The body region 119 of the second dopant type and the epitaxial semiconductor layer 111 of the first dopant type have opposite dopant types. By controlling parameters of ion implantation, such as implantation energy and dosage, a desired depth and a desired doping concentration can be achieved, and the depth of the body region 119 does not exceed an extension depth of the gate conductor 118 in the trench. By use of an additional photoresist mask, lateral extension regions of the body region 111 and the source region 113 can be controlled. Preferably, both of the body region 119 and the source region 121 are adjacent to the trench, and are isolated from the gate conductor 118 by the gate dielectric 117.

Subsequently, by the above-described known deposition process, an interlayer dielectric layer 122 located on the source region 121 is formed, and if necessary, a chemical mechanical planarization process is further performed to obtain a flat surface. The interlayer dielectric layer 122 covers the top surfaces of the source region 121 and the gate conductor 118, and a portion, which is located on the upper surface of the epitaxial semiconductor layer 111, of the gate oxide layer may be removed by etching after the source region is formed, or may be conformal with the interlayer dielectric layer 122 and located on the source region 121 without being removed. By use of the above-described known etching process and ion implantation process, a body contact region 120 of the second dopant type is formed in the body region 119; by use of the above-described known etching process, a conductive channel penetrating the interlayer dielectric layer 122 and the source region 121 to reach the body contact region 120 is formed, a source electrode 123 is formed on the interlayer dielectric layer 122, and the source electrode 123 is connected to the body contact region 120 via the conductive channel.

Subsequently, by use of the above-described known deposition process, the drain electrode 124 is formed on the second surface of the semiconductor substrate 101 which has been thinned by thinning technique.

In the above embodiments, the source electrode 123, the gate conductor 118, the shielding conductor 114, and the drain electrode 124 may each be formed of a conductive material including a metal material, such as an aluminum alloy or copper.

In the above description, technical details such as composition and etching process for each layer are not explained in detail. However, it should be understood by those skilled in the art that a layer/region (or the like) of a desired shape can be formed by various technical means. In addition, in order to form a same structure, those skilled in the art may devise methods that are not exactly the same as those described above. In addition, although each embodiment has been described separately above, this does not mean that the measures in each embodiment cannot be advantageously used in combination.

Embodiments of the present disclosure are described above. However, these embodiments are for illustrative purposes only and are not intended to limit the scope of the present invention. The scope of the present invention is defined by the appended claims and their equivalents. Without departing from the scope of the present disclosure, a variety of substitutions and modifications may be made by those skilled in the art which should fall within the scope of the present invention.

What is claimed is:

1. A method for manufacturing a split-gate MOSFET, wherein the method comprises:
forming a cavity extending from an upper surface of a semiconductor layer of a first dopant type to an interior of the semiconductor layer;
removing a portion, which is located on a sidewall of the cavity, of the semiconductor layer to form a first trench;
forming a second trench communicated with the first trench, wherein the first trench and the second trench extend in a same direction;
forming a first dielectric layer covering an inner surface of the second trench, and a second dielectric layer covering an inner surface of the first trench;
forming a first conductor which is located in the second trench and is isolated from the semiconductor layer by the first dielectric layer;
forming a third dielectric layer covering a surface of the first conductor;
forming a second conductor located in the first trench, wherein the second conductor is isolated from the semiconductor layer by the second dielectric layer, and is isolated from the first conductor by the third dielectric layer; and
forming a body region of a second dopant type which is located in the semiconductor layer and adjacent to the first trench,
wherein an inner diameter of the first trench is larger than that of the second trench.

2. The manufacturing method according to claim 1, wherein an oxidation process is performed to convert the portion, which is located on the sidewall of the cavity, of the semiconductor layer into an oxide layer and the oxide layer is then removed to form the first trench,
wherein an inner diameter of a bottom of the first trench is smaller than an inner diameter of a top of the first trench, and an inner diameter of the second trench substantially keeps consistent with the inner diameter of the bottom of the first trench.

3. The manufacturing method according to claim 2, wherein an inner diameter of the oxide layer gradually increases from bottom to top, so that the inner diameter of the first trench gradually increases from bottom to top.

4. The manufacturing method according to claim 2, wherein a thickness of the portion, which is located on the sidewall of the cavity and to be removed, of the semiconductor layer is controlled by adjusting oxidant concentration in the oxidation process.

5. The manufacturing method according to claim 1, wherein a thickness of the first dielectric layer is greater than a thickness of the second dielectric layer.

6. The manufacturing method according to claim 1, further comprising:
forming a source region of the first dopant type in the body region;
forming an interlayer dielectric layer on the source region; and
forming a source electrode on the interlayer dielectric layer.

7. The manufacturing method according to claim 1, further comprising:
forming a body contact region of the second dopant type in the body region; and
forming a conductive channel penetrating the interlayer dielectric layer and the source region to reach the body contact region, wherein the source electrode is connected to the body contact region via the conductive channel.

8. The manufacturing method according to claim 1, wherein the semiconductor layer is formed on a semiconductor substrate, the semiconductor substrate is located on a lower surface of the semiconductor layer, the upper surface of the semiconductor layer is opposite to the lower surface of the semiconductor layer, and the manufacturing method further comprises:
forming a drain electrode on the lower surface of the semiconductor substrate.

9. A split-gate MOSFET, comprising:
a semiconductor layer of a first dopant type;
a first trench extending from an upper surface of the semiconductor layer to an interior of the semiconductor layer, a second trench communicated with a bottom of the first trench, wherein the first trench and the second trench extending in a same direction;
a first dielectric layer covering an inner surface of the second trench, a second dielectric layer covering an inner surface of the first trench, and a third dielectric layer between the first dielectric layer and the second dielectric layer;
a first conductor located in the second trench and a second conductor located in the first trench, wherein the first conductor is isolated from the semiconductor layer by the first dielectric layer, the second conductor is isolated from the semiconductor layer by the second dielectric layer, and the first conductor is isolated from the second conductor by the third dielectric layer; and
a body region of a second dopant type which is located in the semiconductor layer and adjacent to the first trench,
wherein the first trench is formed by removing a portion, which is located on a sidewall of a cavity, of the semiconductor layer, and an inner diameter of the first trench is larger than an inner diameter of the second trench.

10. The split-gate MOSFET according to claim 9, wherein the inner diameter of the first trench gradually increases from bottom to top.

11. The split-gate MOSFET according to claim 9, wherein an inner diameter of a bottom of the first trench is smaller than an inner diameter of a top of the first trench, and an inner diameter of the second trench substantially keeps consistent with the inner diameter of the bottom of the first trench.

12. The split-gate MOSFET according to claim 9, wherein a thickness of the first dielectric layer is greater than a thickness of the second dielectric layer.

13. The split-gate MOSFET according to claim 9, further comprising:
a source region of the first dopant type in the body region;
an interlayer dielectric layer on the source region; and
a source electrode located on the interlayer dielectric layer.

14. The split-gate MOSFET according to claim 9, further comprising:
a body contact region of the second dopant type in the body region; and
a conductive channel penetrating the interlayer dielectric layer and the source region to reach the body contact region, wherein the source electrode is connected to the body contact region via the conductive channel.

15. The split-gate MOSFET according to claim 9, further comprising:
a semiconductor substrate located on a lower surface of the semiconductor layer, wherein the upper surface of the semiconductor layer is opposite to the lower surface of the semiconductor layer; and
a drain electrode located on the lower surface of the semiconductor substrate.
